(19) United States
(12) Patent Application Publication
(10) Pub. No.: US 2026/0076271 A1
(43) Pub. Date: Mar. 12, 2026

(54) ELECTRONIC PACKAGE HAVING STEPPED STACKED SUBSTRATE STRUCTURE

(71) Applicant: QUALCOMM Incorporated, San Diego, CA (US)

(72) Inventors: Manuel ALDRETE, Encinitas, CA (US); Aniket PATIL, San Diego, CA (US); Rajneesh KUMAR, San Diego, CA (US); Piyush GUPTA, San Diego, CA (US)

(21) Appl. No.: 18/883,570

(22) Filed: Sep. 12, 2024

(51) Int. Cl. H01L 23/498; H01L 23/367; H10B 80/00

(52) U.S. Cl. CPC H10W 90/701; H10B 80/00; H10W 40/22; H10W 70/685

(57) ABSTRACT

In an aspect, an electronic device includes a plurality of stacked substrates, each substrate includes a first planar surface and a second planar surface opposite the first planar surface. Adjacent substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates, A redistribution layer underlies the stacked substrates. Conductive pillars extend in a direction perpendicular to the planar connection surface of each upper substrate of the adjacent substrates to electrically connect the electronic components of each upper substrate to the redistribution layer.

### FIELD OF DISCLOSURE

The present disclosure generally relates to electronic packaging, and more particularly, to an electronic package including stepped stacked substrates.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system on a chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

The electronic packaging industry has pursued the path of miniaturization, seeking to pack more functionality into smaller devices. However, as the industry pushes for greater circuit density and performance, there is a shift toward reducing the size of such devices, which introduces package miniaturization challenges.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose of presenting certain concepts relating to one or more aspects relating to the mechanisms disclosed herein in a simplified form to precede the detailed description presented below.

In an aspect, an electronic device includes a plurality of stacked substrates, each substrate including a first planar surface, a second planar surface opposite the first planar surface, wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates; a redistribution layer underlying the plurality of stacked substrates; and one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.

In an aspect, a stacked substrate structure includes a plurality of stacked substrates, each substrate including a first planar surface, a second planar surface opposite the first planar surface, wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates; a redistribution layer overlying the plurality of stacked substrates; and one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.

In an aspect, a method of forming stacked substrate structure includes stacking a plurality of substrates, each substrate including a first planar surface, a second planar surface opposite the first planar surface, wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates; forming a redistribution layer overlying the plurality of substrates; and forming one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 shows an example of a typical electronic package in which a memory substrate is connected to a processor, such as a flip-chip processor, according to aspects of the disclosure.

FIG. 2 shows an example electronic package in which a stack of memory substrates is electrically connected to a processor substrate, according to aspects of the disclosure.

FIG. 3A through FIG. 3F show exemplary steps that may be used to manufacture an electronic package, according to aspects of the disclosure.

FIG. 4 illustrates an electronic package having thermal dissipation components, according to aspects of the disclosure.

FIG. 5 illustrates an electronic package having thermal dissipation components, according to aspects of the disclosure.

FIG. 6 is a flowchart showing an example of operations that may be executed to fabricate an electronic package, according to aspects of the disclosure.

FIG. 7 illustrates a profile view of a package that includes a surface mount substrate, an integrated device, and an integrated passive device, according to aspects of the disclosure.

FIG. 8 illustrates an example method for providing or fabricating a package that includes an integrated device comprising a power splitter, according to aspects of the disclosure.

FIG. 9 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC), according to aspects of the disclosure.

### DETAILED DESCRIPTION

Aspects of the present disclosure are illustrated in the following description, and related drawings are directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. It will also be understood that when a layer is described as “over,” “overlying,” “under,” “underlying,” another layer does not necessarily preclude the use of intermediate layers and/or materials that may otherwise be used to ensure adhesion between the layers. Still further, it will be understood that when a layer is described as “over,” “overlying,” “under,” “underlying,” another layer that such terms are used with reference to the orientations of such layers as depicted in the reference frame shown in the corresponding figures.

In an aspect, the present disclosure is directed to miniaturization of a multi-circuit microelectronic package. In various aspects, the disclosure describes electronic packages employing a compact stepped stack substrate structure. In an aspect, a substrate may be a layer or material upon which electronic components (e.g., active and/or passive components) are mounted, assembled, and/or formed. In an aspect, the stacked substrate structure includes planar connection surfaces respectively associated with each of the substrates of the stacked substrate structure. In an aspect, conductive pillars extend perpendicularly from the planar connection surfaces to engage a redistribution layer. In an aspect, the conductive pillars provide a conductive path between the substrates of the stacked substrate structure and a further substrate. In an aspect, the disclosed electronic package is applied in the context of connecting stacked memory substrates (e.g., the stacked substrate structure) with a processor substrate (e.g., the further substrate) so as to reduce the size of the electronic package and limit the problems associated with long conductive paths between the memory substrates and the processor substrate.

Having long conductive paths between the substrates in an electronic package has several pitfalls. For example, long conductive paths between memory substrates and a processor substrate can lead to several performance and reliability issues. Longer paths mean that signals take more time to travel between the memory and the processor, resulting in increased latency. This delay can slow down the overall performance of the system, as the processor has to wait longer for data from the memory. The time it takes to access memory (read/write operations) increases, which can be particularly detrimental in high-performance computing environments where speed is crucial. Electrical signals can degrade, losing their strength and clarity when transmitting signals over long conductive paths. This can lead to data corruption or errors in the transmitted information. Longer conductive paths are more susceptible to electromagnetic interference (EMI) and crosstalk from adjacent wires or components. This can introduce noise into the signals, further degrading their integrity. Still further, long conductive paths between substrates can increase power consumption and may require additional power regulation components, which can increase the design complexity and costs.

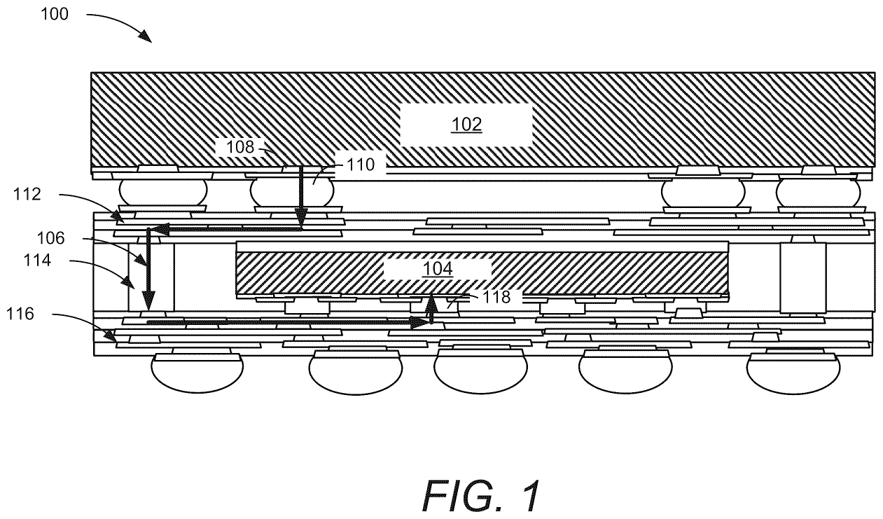

FIG. 1 shows an example of a typical electronic package 100 in which a memory substrate 102 is connected to a processor 104, such as a flip-chip processor, according to aspects of the disclosure. In this example, there is a relatively long conductive path between the memory substrate 102 and the processor 104. Once such conductive path 106 is depicted by arrows. In this example, the conductive path 106 includes terminal 108 of the memory substrate 102, the solder ball 110, a first redistribution layer (RDL) 112, conductive column 114, a second RDL 116, and terminal 118 of the processor 104. In an aspect, an RDL is thin layer of metal interconnects that is added to the surface of a substrate typically to reroute the connections of devices of the substrate to achieve high connection density. As shown in FIG. 1, the conductive path 106 is relatively long and is subject to the pitfalls of long conductive paths discussed above.

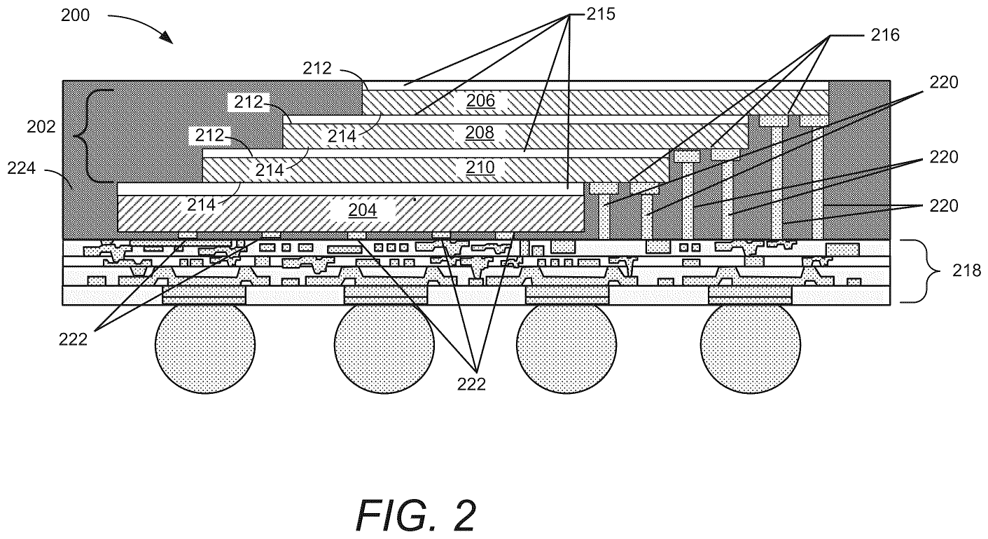

FIG. 2 shows an example electronic package 200 in which a stack of memory substrates 202 are electrically connected to a processor substrate 204, according to aspects of the disclosure. Each memory substrate 206, 208, and 210 has a first planar surface 212 and a second planar surface 214 opposite the first planar surface 212. In an aspect, the memory substrates 206, 208, 210, and processor substrate 204 may be secured with one another by adhesive layers 215, which may be ignored in determining whether memory substrates are adjacent to one another. Adjacent memory substrates (e.g., memory substrate 206 is adjacent memory substrate 208, memory substrate 208 is adjacent to both memory substrates 208 and 210, and memory substrate 210 is adjacent memory substrate 208) of the stack of memory substrates 202 are stacked so that the second planar surface 214 of each upper substrate (e.g., memory substrate 206 is an upper memory substrate with respect to memory substrate 208, memory substrate 208 is an upper memory substrate with respect to memory substrate 210) of the adjacent substrates (e.g., memory substrate 208 and memory substrate 210 are adjacent substrates) extends beyond the first planar surface 212 of each lower substrate (e.g., memory substrate 210) of the adjacent memory substrates (e.g., memory substrates 208 and 210) to form planar connection surfaces 216 at the second planar surface 214 of the upper substrate (e.g., memory substrate 208) of the adjacent memory substrates. In this example, the stack of memory substrates 202 forms a stepped structure. However, it will be recognized, based on the teachings of the present disclosure, that the stack of memory substrates 202 may take the form of other step-like structures (e.g., pyramid structures) that facilitate the formation of multiple planar connection surfaces on adjacent memory substrates.

Although the substrates 206, 208, and 210 are discussed in the context of memory substrates, it will be recognized, based on the teachings of the present disclosure, that the substrates are not limited to memory substrates. In an aspect, the substrates may be any type of substrate. In an aspect, substrates may include other types of active substrates, passive substrates (e.g., substrates having only passive electronic components), or any combination of such substrates.

The electronic package 200 provides a shortened conductive path between the memory substrates 206, 208, and 210 and processor substrate 204. As shown, an RDL 218 underlies the stacked memory substrates 202. One or more conductive pillars 220 extend from the planar connection surface 216 of each upper substrate of the adjacent substrates to electrically connect one or more electronic components (e.g., memory components) of each upper substrate to the RDL 218. The conductive pillars 220 extend perpendicularly from the planar connection surfaces 216 of each upper substrate to the RDL 218. In turn, terminals 222 of the processor substrate 204 electrically connect the RDL 218 to the processor substrate 204 to complete the conductive path between the electronic components of the memory substrates 206, 208, and 210 to the processor substrate 204.

In this example, an over-molding material 224 at least partially surrounds the stack of memory substrates 202, the processor 204, and conductive pillars 220. In an aspect, the over-molding material 224 secures such components within the electronic package 200 to provide mechanical strength and protection. In an aspect, the over-molding material 224 may also provide heat dissipation from the electronic package 200 to the ambient environment. In an aspect, the over-molding material 224 may comprise thermoplastics, thermosets, and/or elastomers. However, any material having the required durability, flexibility, thermal resistance, and electrical insulation properties may be used for the over-molding material 224.

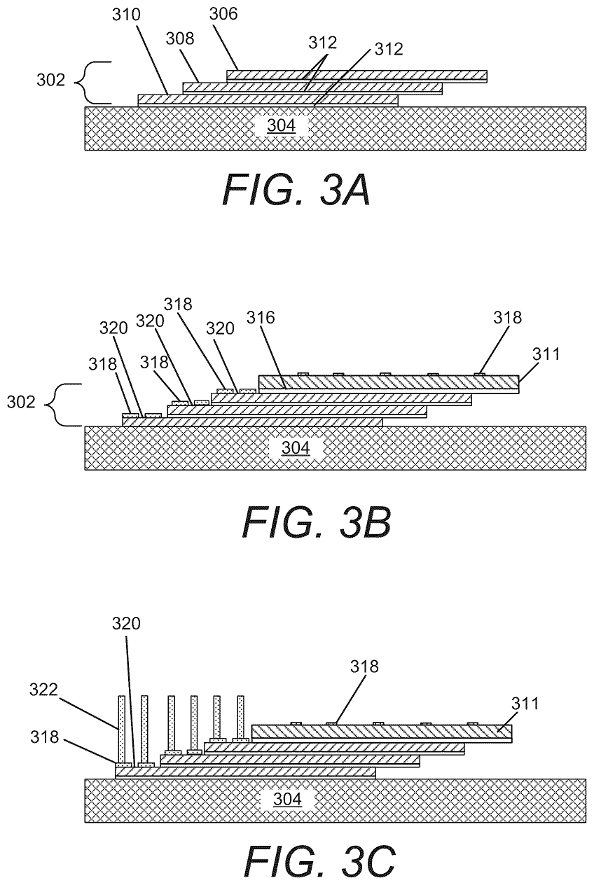

FIG. 3A through FIG. 3F show exemplary steps that may be used to manufacture an electronic package, according to aspects of the disclosure. In FIG. 3A, a stack of memory substrates 302 is formed on an RDL carrier 304. The stack of memory substrates 302 includes memory substrates 306, 308, and 310 that are secured with one another by respective adhesive layers 312, while the lowermost memory substrate 310 is secured to the RDL carrier 304 by an adhesive layer 314.

In FIG. 3B, a flip chip processor 311 is attached to overlie the stack of memory substrates 302 by, for example, an adhesive layer 316. Additionally, conductive terminals 318 are formed over the upper surface of the flip chip processor 311, and the planar connection surface 320 of each memory substrate 306, 308, and 310.

In FIG. 3C, a conductive pillar 322 is attached to each conductive terminal 318 at the planar connection surface 320 of each memory substrate 306, 308, and 310. In an aspect, the conductive pillars 322 may be attached to the planar connection surfaces 320 using a vertical wire bonding process. As shown, the conductive pillars 322 are applied so that they extend perpendicularly to their respective planar connection surfaces 320. Here, the conductive pillars 322 extend beyond the conductive terminals 318 at the upper surface of the flip chip processor 311.

In FIG. 3D, an over-molding material 324 is applied over the stack of memory substrates, flip chip processor, and conductive pillars. The over-molding material 324 and upper ends of the conductor pillars 322 are subject to a grinding process such that the upper portions of the conductive pillars 322 are level with the conductive terminals 318 of the flip chip processor 311.

In FIG. 3E, an RDL layer 326 is formed over the upper portions of the conductive pillars 322 and conductive terminals 318 of the flip chip processor 311 to provide a conductive path between each memory substrate 306, 308, and 310 of the stack of memory substrates 302 and the flip chip processor 311. As shown, the conductive pillars 322 extend from the respective planar connection surfaces 320 so as to be perpendicular to the RDL layer 326. In an aspect, the conductive pillars 322 form linear conductive paths that proceed directly from each memory substrate 306, 308, and 310 of the stack of memory substrates 302 and the RDL layer 326. Additionally, solder interconnects 328 are attached to the RDL layer 326 to facilitate connection of the electronic package to other components on, for example, a printed circuit board (PCB) or similar multi-component carrying structure.

In FIG. 3F, the fully formed electronic package 330 is subject to a singulation process to remove the RDL carrier 304. In FIG. 3F, the electronic package 330 is shown in an inverted state with respect to the intermediate structures shown in FIG. 3A through FIG. 3E.

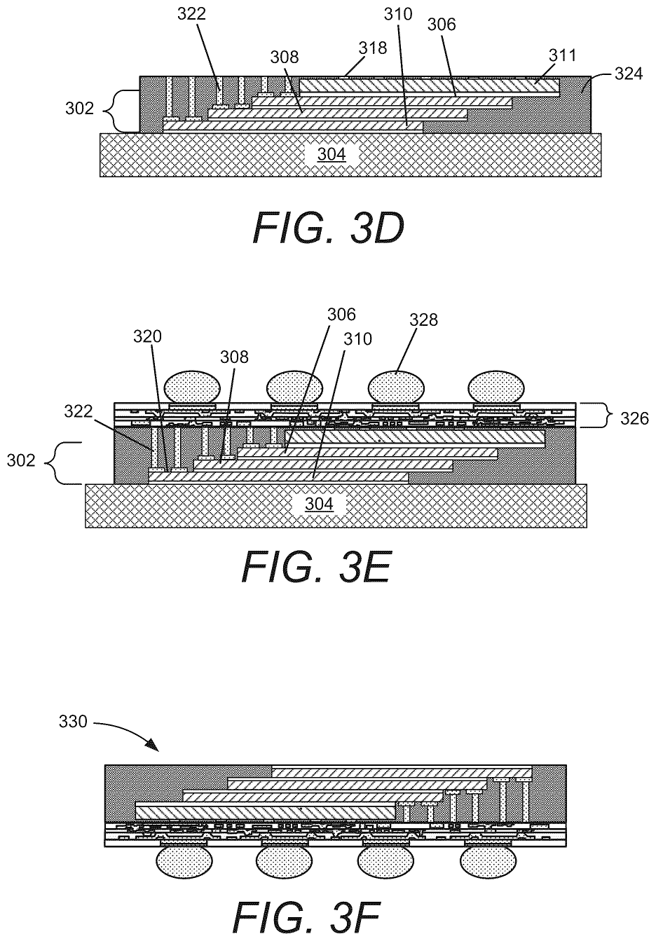

FIG. 4 illustrates an electronic package 400 having thermal dissipation components, according to aspects of the disclosure. In this example, a stairstep structure including planar thermal dissipation surfaces 402, 404, and 406 is formed by the offset memory substrates 408, 410, and 412 and the flip chip processor 414. Thermal dissipation of the heat generated by the components of the electronic package 400 is provided by a heat dissipation structure that comprises metal slugs 418, 420, and 422 respectively overlying the planar thermal dissipation surfaces 402, 404, and 406.

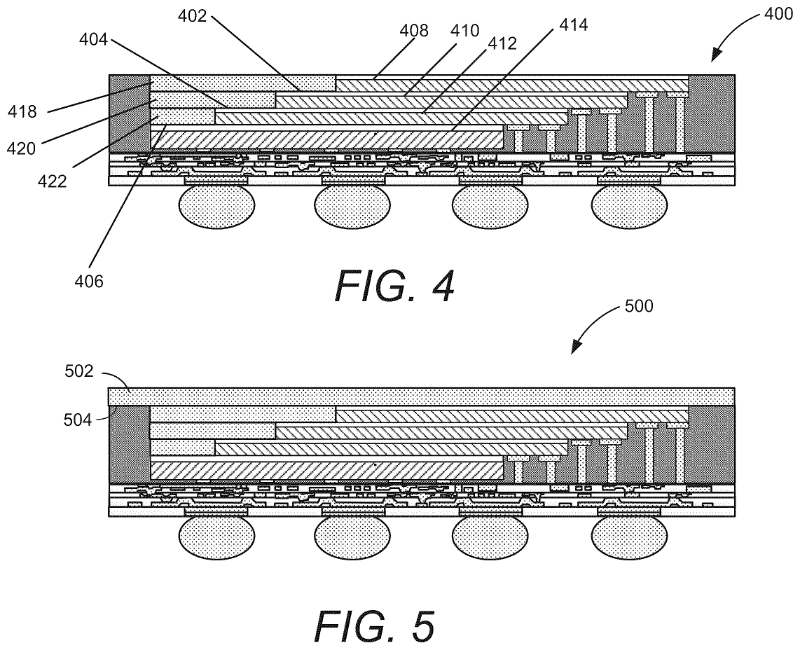

FIG. 5 illustrates an electronic package 500 having thermal dissipation components, according to aspects of the disclosure. The electronic package 500 shown in FIG. 5 is similar to the electronic package 400 shown in FIG. 4. However, electronic package 500 includes an additional metal slug 502 at the top surface 504 of the electronic package 500 to provide additional thermal dissipation from the components of the electronic package 500 to, for example, the ambient environment.

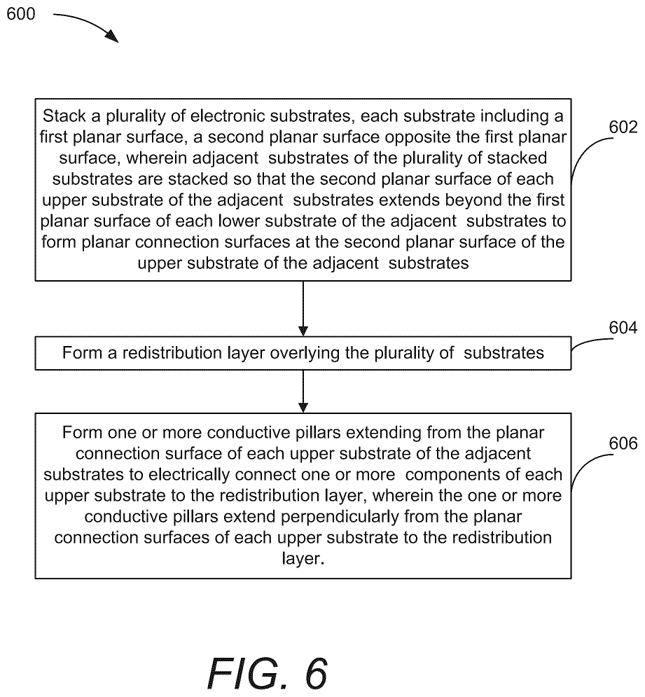

FIG. 6 is a flowchart 600 showing an example of operations that may be executed to fabricate an electronic package, according to aspects of the disclosure. At operation 602, a plurality of substrates are stacked, each substrate including a first planar surface, a second planar surface opposite the first planar surface, wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates.

At operation 604, a redistribution layer overlying the plurality of substrates is formed. At operation 606, one or more conductive pillars are formed that extend from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.

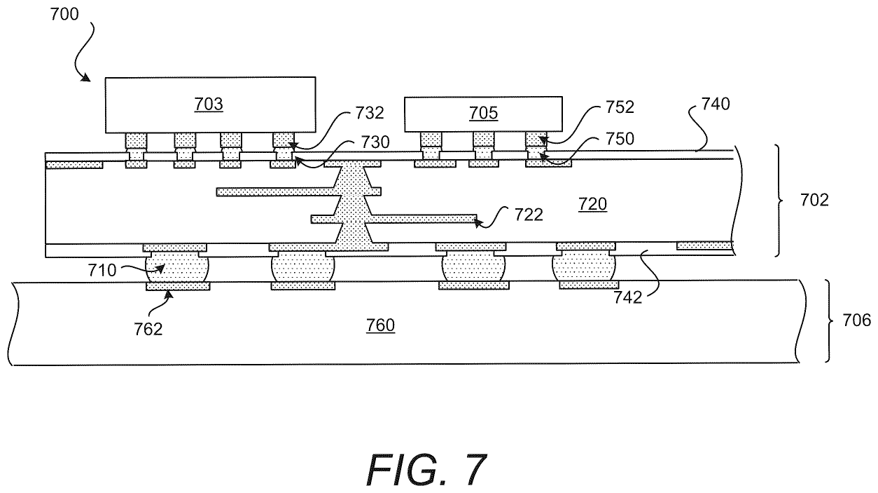

FIG. 7 illustrates a profile view of a package 700 that includes a surface mount substrate 702, an integrated device 703, and an integrated passive device 705, according to aspects of the disclosure. The package 700 may be coupled to a printed circuit board (PCB) 706 through a plurality of solder interconnects 710. The PCB 706 may include at least one board dielectric layer 760 and a plurality of board interconnects 762.

The surface mount substrate 702 includes at least one dielectric layer 720 (e.g., substrate dielectric layer), a plurality of interconnects 722 (e.g., substrate interconnects), a solder resist layer 740 and a solder resist layer 742. The integrated device 703 may be coupled to the surface mount substrate 702 through a plurality of solder interconnects 730. The integrated device 703 may be coupled to the surface mount substrate 702 through a plurality of pillar interconnects 732 and the plurality of solder interconnects 730. The integrated passive device 705 may be coupled to the surface mount substrate 702 through a plurality of solder interconnects 750. The integrated passive device 705 may be coupled to the surface mount substrate 702 through a plurality of pillar interconnects 752 and the plurality of solder interconnects 750.

The package (e.g., 700) may be implemented in a radio frequency (RF) package. The RF package may be a radio frequency front end (RFFE) package. A package (e.g., 700) may be configured to provide Wireless Fidelity (WiFi) communication and/or cellular communication (e.g., 2G, 3G, 4G, 5G). The package (e.g., 700) may be configured to support Global System for Mobile (GSM) Communications, Universal Mobile Telecommunications System (UMTS), and/or Long-Term Evolution (LTE). The package (e.g., 700) may be configured to transmit and receive signals having different frequencies and/or communication protocols.

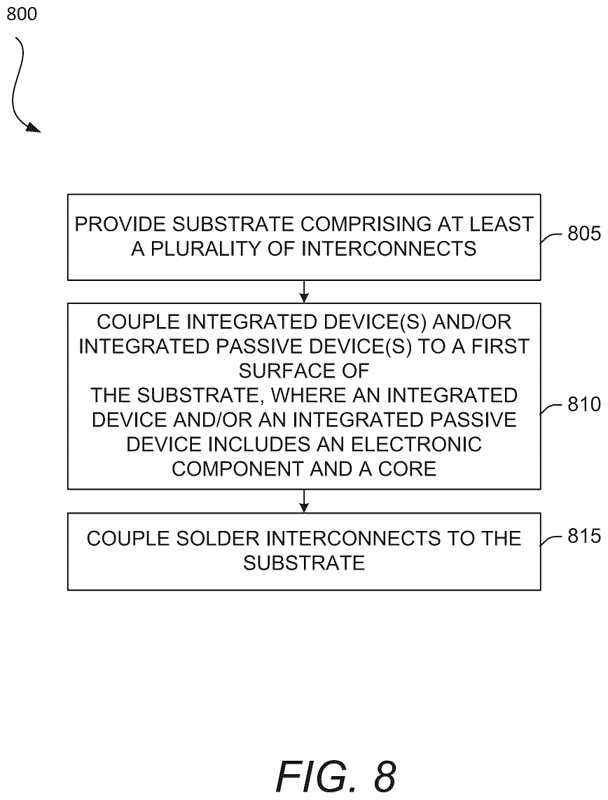

FIG. 8 illustrates an example method 800 for providing or fabricating a package that includes an integrated device comprising a power splitter, according to aspects of the disclosure. In some implementations, the method 800 of FIG. 8 may be used to provide or fabricate the package 700 of FIG. 7 described in the disclosure. However, the method 800 may be used to provide or fabricate any of the packages described in the disclosure.

It should be noted that the method of FIG. 8 may combine one or more processes in order to simplify and/or clarify the method for providing or fabricating a package that includes an integrated device comprising adjacent logic circuits having back-to-back vias, according to aspects of the disclosure. In some implementations, the order of the processes may be changed or modified.

The method provides (at 805) a substrate (e.g., 702). The substrate 702 may be provided by a supplier or fabricated. The substrate 702 includes at least one dielectric layer 720, and a plurality of interconnects 722. The substrate 702 may include an embedded trace substrate (ETS). In some implementations, the at least one dielectric layer 720 may include prepreg layers.

The method couples (at 810) at least one integrated device (e.g., 703) to the first surface of the substrate (e.g., 702). For example, the integrated device 703 may be coupled to the substrate 702 through the plurality of pillar interconnects 732 and the plurality of solder interconnects 730. The plurality of pillar interconnects 732 may be optional. The plurality of solder interconnects 730 are coupled to the plurality of interconnects 722. A solder reflow process may be used to couple the integrated device 703 to the plurality of interconnects through the plurality of solder interconnects 730.

The method also couples (at 810) at least one integrated passive device (e.g., 705) to the first surface of the substrate (e.g., 702). For example, the integrated passive device 705 may be coupled to the substrate 702 through the plurality of pillar interconnects 752 and the plurality of solder interconnects 750. The plurality of pillar interconnects 752 may be optional. The plurality of solder interconnects 750 are coupled to the plurality of interconnects 722. A solder reflow process may be used to couple the integrated passive device 705 to the plurality of interconnects through the plurality of solder interconnects 750.

The method couples (at 815) a plurality of solder interconnects (e.g., 710) to the second surface of the substrate (e.g., 702). A solder reflow process may be used to couple the plurality of solder interconnects 710 to the substrate.

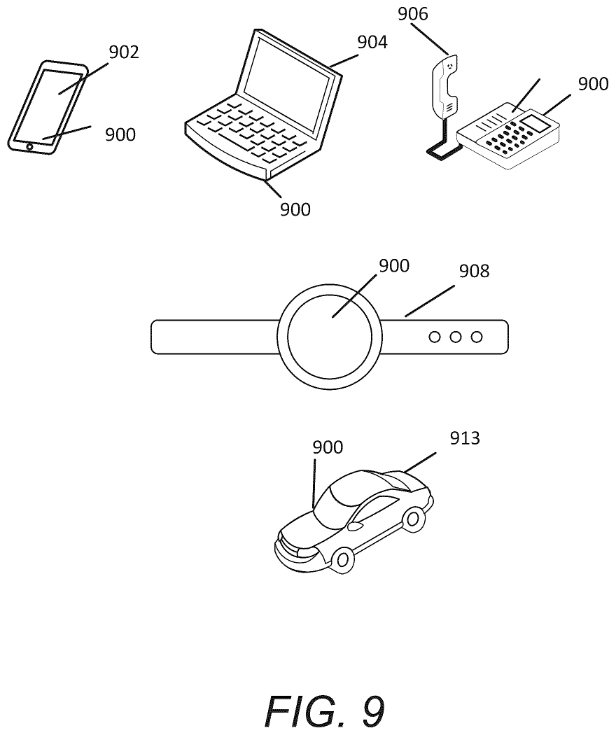

FIG. 9 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 902, a laptop computer device 904, a fixed location terminal device 906, a wearable device 908, or automotive vehicle 913 may include a device 900 as described herein. The device 900 may be, for example, any of the devices and/or integrated circuit (IC) packages described herein. The devices 902, 904, 906 and 908 and the vehicle 913 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:
Aspect 1—An electronic device, comprising: a plurality of stacked substrates, each substrate including a first planar surface, a second planar surface opposite the first planar surface, wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates; a redistribution layer underlying the plurality of stacked substrates; and one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.
Aspect 2—The electronic device of aspect 1, further comprising: an over-molding material at least partially surrounding the plurality of stacked substrates and the one or more conductive pillars.
Aspect 3—The electronic device of aspects 1 or 2, wherein: at least one of the substrates of the plurality of stacked substrates comprises a memory substrate.
Aspect 4—The electronic device of aspects 1 through 3, wherein: at least one of the substrates of the plurality of substrates comprises a passive component substrate.
Aspect 5—The electronic device of aspects 1 through 4, further comprising: a further substrate having a first planar surface and a second planar surface opposite the first planar surface, wherein the first planar surface of the further substrate is disposed adjacent the second planar surface of a lowermost substrate of the plurality of stacked substrates.
Aspect 6—The electronic device of aspect 5, wherein: the further substrate comprises a flip chip processor.
Aspect 7—The electronic device of aspects 1 through 5, wherein: the first planar surface of each lower substrate of the adjacent substrates extends beyond the second planar surface of each upper substrate of the adjacent substrates to form thermal dissipation surfaces at the first planar surface of the lower substrate of the adjacent substrates; and the electronic device further comprising one or more metal slugs overlying one or more of the thermal dissipation surfaces.
Aspect 8—The electronic device of aspects 1 through 7, wherein the electronic device comprises at least one of: a music player; a video player; an entertainment unit; a navigation device; a communications device; a mobile device; a mobile phone; a smartphone; a personal digital assistant; a fixed location terminal; a tablet computer; a computer; a wearable device; a laptop computer; a server; an internet of things (IoT) device; or a device in an automotive vehicle.
Aspect 9—A stacked substrate structure, comprising: a plurality of stacked substrates, each substrate including a first planar surface, a second planar surface opposite the first planar surface, wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates; a redistribution layer overlying the plurality of stacked substrates; and one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.
Aspect 10—The stacked substrate structure of aspect 9, further comprising: an over-molding material at least partially surrounding the plurality of stacked substrates and the one or more conductive pillars.
Aspect 11—The stacked substrate structure of aspects 9 or 10, wherein: at least one of the substrates of the plurality of stacked substrates comprises a memory substrate.
Aspect 12—The stacked substrate structure of aspects 9 through 11, wherein: at least one of the substrates of the plurality of substrates comprises a passive component substrate.
Aspect 13—The stacked substrate structure of aspects 9 through 12, further comprising: a further substrate having a first planar surface and a second planar surface opposite the first planar surface, wherein the first planar surface of the further substrate is disposed adjacent the second planar surface of a lowermost substrate of the plurality of stacked substrates.
Aspect 14—The stacked substrate structure of aspect 13, wherein: the further substrate comprises a flip chip processor.
Aspect 15—The stacked substrate structure of aspects 9 through 14, wherein: the first planar surface of each lower substrate of the adjacent substrates extends beyond the second planar surface of each upper substrate of the adjacent substrates to form thermal dissipation surfaces at the first planar surface of the lower substrate of the adjacent substrates; and the stacked substrate structure further comprising one or more metal slugs overlying one or more of the thermal dissipation surfaces.
Aspect 16—A method of forming stacked substrate structure, comprising: stacking a plurality of substrates, each substrate including a first planar surface, a second planar surface opposite the first planar surface, wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates; forming a redistribution layer overlying the plurality of substrates; and forming one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.
Aspect 17—The method of aspect 16, further comprising: performing an over-molding operation to at least partially surround the plurality of stacked substrates and the one or more conductive pillars with an over-molding material.
Aspect 18—The method of aspects 16 through 18, wherein: at least one of the substrates of the plurality of stacked substrates comprises a memory substrate.
Aspect 19—The method of aspects 16 through 18, further comprising: attaching a flip chip processor having a first planar surface and a second planar surface opposite the first planar surface so that the first planar surface of the flip chip processor is disposed adjacent the second planar surface of a lowermost substrate of the plurality of substrates.
Aspect 20—The method of aspects 16 through 19, wherein: the first planar surface of each lower substrate of the adjacent substrates extends beyond the second planar surface of each upper substrate of the adjacent substrates to form thermal dissipation surfaces at the first planar surface of the lower substrate of the adjacent substrates; and the method further comprising: forming one or more metal slugs over the one or more of the thermal dissipation surfaces.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration. ” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under-bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
a plurality of stacked substrates, each substrate including
a first planar surface,
a second planar surface opposite the first planar surface,
wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates;
a redistribution layer underlying the plurality of stacked substrates; and
one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.

2. The electronic device of claim 1, further comprising:
an over-molding material at least partially surrounding the plurality of stacked substrates and the one or more conductive pillars.

3. The electronic device of claim 1, wherein:
at least one of the substrates of the plurality of stacked substrates comprises a memory substrate.

4. The electronic device of claim 1, wherein:
at least one of the substrates of the plurality of substrates comprises a passive component substrate.

5. The electronic device of claim 1, further comprising:
a further substrate having a first planar surface and a second planar surface opposite the first planar surface, wherein the first planar surface of the further substrate is disposed adjacent the second planar surface of a lowermost substrate of the plurality of stacked substrates.

6. The electronic device of claim 5, wherein:
the further substrate comprises a flip chip processor.

7. The electronic device of claim 1, wherein:
the first planar surface of each lower substrate of the adjacent substrates extends beyond the second planar surface of each upper substrate of the adjacent substrates to form thermal dissipation surfaces at the first planar surface of the lower substrate of the adjacent substrates; and
the electronic device further comprising one or more metal slugs overlying one or more of the thermal dissipation surfaces.

8. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

9. A stacked substrate structure, comprising:
a plurality of stacked substrates, each substrate including
a first planar surface,
a second planar surface opposite the first planar surface,
wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates;
a redistribution layer overlying the plurality of stacked substrates; and
one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.

10. The stacked substrate structure of claim 9, further comprising:
an over-molding material at least partially surrounding the plurality of stacked substrates and the one or more conductive pillars.

11. The stacked substrate structure of claim 9, wherein:
at least one of the substrates of the plurality of stacked substrates comprises a memory substrate.

12. The stacked substrate structure of claim 9, wherein:
at least one of the substrates of the plurality of substrates comprises a passive component substrate.

13. The stacked substrate structure of claim 9, further comprising:
a further substrate having a first planar surface and a second planar surface opposite the first planar surface, wherein the first planar surface of the further substrate is disposed adjacent the second planar surface of a lowermost substrate of the plurality of stacked substrates.

14. The stacked substrate structure of claim 13, wherein:
the further substrate comprises a flip chip processor.

15. The stacked substrate structure of claim 9, wherein:
the first planar surface of each lower substrate of the adjacent substrates extends beyond the second planar surface of each upper substrate of the adjacent substrates to form thermal dissipation surfaces at the first planar surface of the lower substrate of the adjacent substrates; and
the stacked substrate structure further comprising one or more metal slugs overlying one or more of the thermal dissipation surfaces.

16. A method of forming stacked substrate structure, comprising:
stacking a plurality of substrates, each substrate including
a first planar surface,
a second planar surface opposite the first planar surface,
wherein adjacent substrates of the plurality of stacked substrates are stacked so that the second planar surface of each upper substrate of the adjacent substrates extends beyond the first planar surface of each lower substrate of the adjacent substrates to form planar connection surfaces at the second planar surface of the upper substrate of the adjacent substrates;
forming a redistribution layer overlying the plurality of substrates; and
forming one or more conductive pillars extending from the planar connection surface of each upper substrate of the adjacent substrates to electrically connect one or more electronic components of each upper substrate to the redistribution layer, wherein the one or more conductive pillars extend perpendicularly from the planar connection surfaces of each upper substrate to the redistribution layer.

17. The method of claim 16, further comprising:
performing an over-molding operation to at least partially surround the plurality of stacked substrates and the one or more conductive pillars with an over-molding material.

18. The method of claim 16, wherein:
at least one of the substrates of the plurality of stacked substrates comprises a memory substrate.

19. The method of claim 16, further comprising:
attaching a flip chip processor having a first planar surface and a second planar surface opposite the first planar surface so that the first planar surface of the flip chip processor is disposed adjacent the second planar surface of a lowermost substrate of the plurality of substrates.

20. The method of claim 16, wherein:
the first planar surface of each lower substrate of the adjacent substrates extends beyond the second planar surface of each upper substrate of the adjacent substrates to form thermal dissipation surfaces at the first planar surface of the lower substrate of the adjacent substrates; and
the method further comprising:
forming one or more metal slugs over the one or more of the thermal dissipation surfaces.
